(19) United States
(12) Patent Application Publication
(10) Pub. No.: US 2013/0003304 A1
(43) Pub. Date: Jan. 3, 2013

(54) CONICAL HEADED FASTENER FOR A PRINTED WIRING BOARD ASSEMBLY

(75) Inventors: William L. Woods, JR., Kaufman, TX (US); Keith A. Leicht, Sachse, TX (US); Tushar Shete, Richardson, TX (US)

(73) Assignee: Lineage Power Corporation, Plano, TX (US)

(21) Appl. No.: 13/175,212

(22) Filed: Jul. 1, 2011

(51) Int. Cl. H05K 7/20; H05K 13/04; B23P 11/00; H05K 5/00; F16B 35/06

(52) U.S. Cl. 361/707; 361/752; 411/401; 29/525.11; 29/525.02

(57) ABSTRACT

One aspect includes an electronics assembly, including: (1) printed wiring board, (2) a mount and (3) a fastener for securing the printed wiring board to the mount, the fastener including a body configured to pass through a mounting hole on the printed wiring board and engage the mount, the fastener further including a conical head configured to receive a driver torque and further configured to engage a rim of the mounting hole and produce an increasing frictional torque to countervail and eventually balance the driver torque.

### TECHNICAL FIELD

This application is directed, in general, to a fastener for a printed wiring board and, more specifically, to a printed wiring board fastener with a conical head.

### BACKGROUND

The usual industry practice is to use conventional machine screws to attach a printed wiring board to an electronic chassis or heat sink. This practice can present a significant problem even if the printed wiring board and surface of the heat sink or chassis are both flat. When a printed wiring board is attached to a heat transfer device, heat sink, or chassis, the assembly process may cause the printed wiring board to warp and crater, or both, thereby stressing components and solder joints on the board, particularly those in near proximity to the mounting fasteners.

Unfortunately, printed wiring board components and/or solder joints have been failing following manufacture, requiring them to be repaired or replaced at great cost.

### SUMMARY

One aspect provides an electronics assembly that includes: (1) a printed wiring board; (2) a mount; and (3) a fastener for securing the printed wiring board to the mount, the fastener including a body configured to pass through a mounting hole on the printed wiring board and engage the mount, the fastener further including a conical head configured to receive a driver torque and further configured to engage a rim of the mounting hole and produce an increasing frictional torque to countervail and eventually balance the driver torque.

Another aspect includes a fastener for securing a printed wiring board of a printed wiring assembly to a mount, including: (1) a body configured to pass through a mounting hole on the printed wiring board and engage the mount; and (2) a conical head configured to receive a driver torque, the conical head further configured to engage a rim of the mounting hole and produce an increasing frictional torque to countervail and eventually balance the driver torque.

Still another aspect includes a method of manufacturing an electronics assembly, including: (1) locating a printed wiring board having a mounting hole therein over a mount; (2) inserting a fastener having a conical head configured to receive a driver through the mounting hole, the fastener engaging the mount; and (3) driving the fastener until the conical head bears against a rim of the mounting hole, the conical head engaging the rim and producing an increasing frictional torque to countervail and eventually balance a predetermined torque of the driver.

### BRIEF DESCRIPTION

Reference is now made to the following descriptions taken in conjunction with the accompanying drawings, in which:

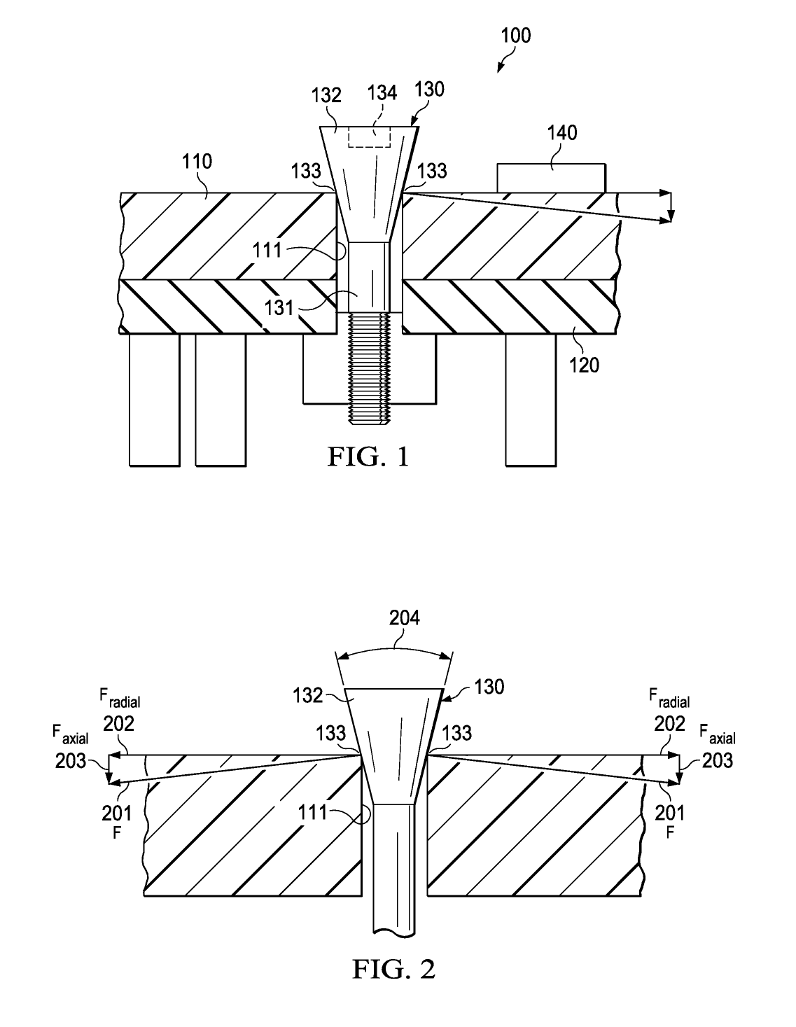

FIG. 1 illustrates an aspect of an electronics assembly showing a cross section view of a portion of a printed wiring board and mount together with a fastener for securing the printed wiring board to the mount;

FIG. 2 illustrates a breakout view of the portion of the embodiment illustrated in FIG. 1 where the conical head of the fastener bears against a rim of the mounting hole;

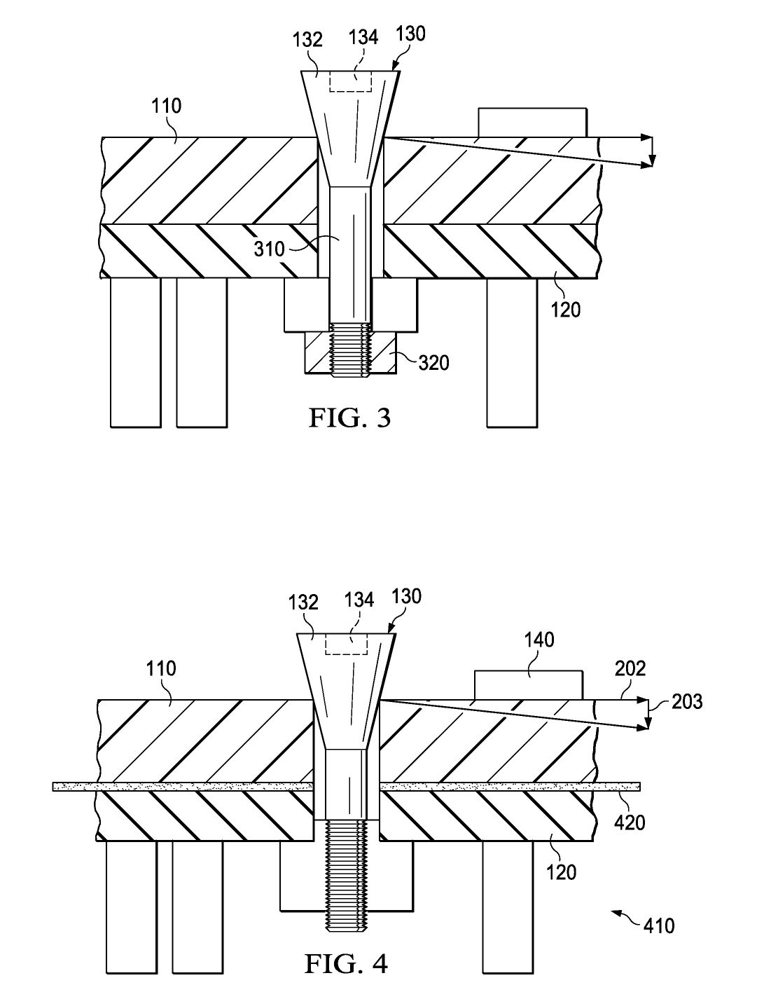

FIG. 3 illustrates an embodiment where the printed wiring board is secured to a mount with a fastener that is a threaded bolt secured by a nut;

FIG. 4 illustrates an embodiment with a printed wiring board mounted on a heat transfer device that is used for the dissipation of heat generated by electronic components mounted on the printed wiring board;

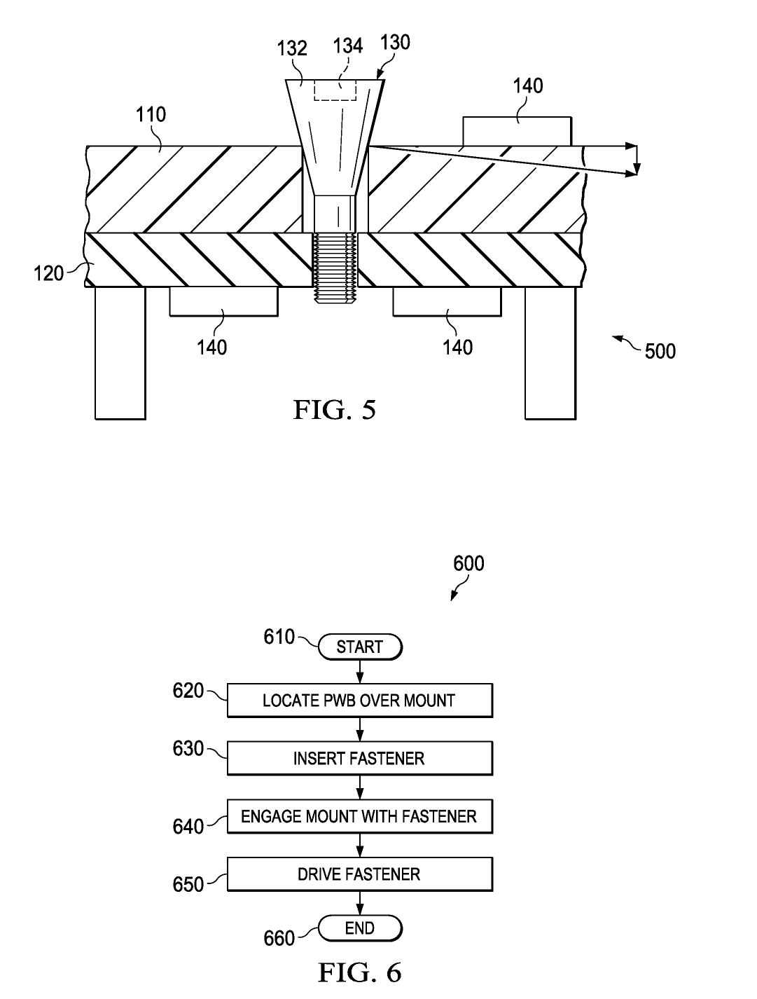

FIG. 5 illustrates an embodiment of a fastener with a conical head used to fasten a printed wiring board to a chassis for an electronic device; and

FIG. 6 is a flow chart illustrating a method of manufacturing an embodiment of an electronics assembly.

### DETAILED DESCRIPTION

It has been found that printed wiring boards mounted to a chassis or heat sink with a fastener can warp or crater the printed wiring board in the proximity of the fastener. Since the fastener is structurally more rigid than the printed wiring board, it has been determined that, as the fastener is tightened on the printed wiring board, the printed wiring board warps in a crater like fashion prior to reaching the stopping torque of the fastener driver.

It has also been found that printed wiring boards mounted to heat plates or heat sinks using thermal materials as gap fillers are especially sensitive to cratering near the fastener. Thermal materials are not usually compressible but are deformable, causing flexure of the printed wiring board in the proximity of fasteners when the layer of thermal material between the printed wiring board and heat plate or heat sink deforms.

Because of this warping and cratering of the printed wiring board in the proximity of the fasteners, electronic components mounted in the area of the fastener are subject to tensile strain and may be damaged to such an extent that they fail. The cratering can also damage solder lines near the fastener.

The torque used to drive a conventional machine screw creates excessive axial loading and forces on the printed wiring board causing the board to warp or crater, or both, during the application of such torque. Failure of components and solder joints in the areas of the printed wiring board subjected to tensile strain is primarily caused by the axial loading placed on the printed wiring board when tightening a fastener by applying the torque necessary to hold it in position. Surface mount ceramic capacitors are especially susceptible to tensile strain damage. Interestingly, surface mount ceramic capacitors are tolerant of compressive strain.

At the present time, frictional torque on the underside of the screw head produces the torque to countervail and balance driving torque on the machine screw, which frictional torque is a direct function of axial loading on the printed wiring board. Higher torque may be required when attaching a printed wiring board to a heat sink in order to assure a consistent setting of the fastener. Contact between the two surfaces is required to minimize the thermal impedance at the interface. Thus, the mounting of a printed wiring board on a heat sink is especially susceptible to the creation of component or solder joint failures in the proximity of the fastener or fasteners due to the potential for excess axial force being applied to the printed wiring board because of the driver torque required to set the fastener.

What is needed is a way to reach the frictional torque required to countervail and eventually balance the driver torque necessary to set the fastener and stop the driver, without either increasing the footprint of the fastening method or imposing significant axial compressive loading or impact forces on the printed wiring board such that significant strain damages adjacent components. Of course, the fastening method or fastener must also provide sufficient holding force to keep the printed wiring board mounted to the chassis or in contact with the heat sink.

Turning initially to FIG. 1, illustrated is an aspect of an electronics assembly 100 showing a cross section view of a portion of a printed wiring board 110 and mount 120 together with a fastener 130 securing the printed wiring board 110 to the mount 120. The fastener 130 has a body 131 configured to pass through a mounting hole 111 on the printed wiring board 110 and engage the mount 120. As used herein the term fastener 130 includes screws, bolts and other threaded fasteners 130 as well as any other type of fastener 130 to which the description herein may be applicable. In the illustrated embodiment, the fastener 130 has a conical head 132 configured to bear against a rim 133 of the mounting hole 111. The term rim 133 includes the circumferential edge of the mounting hole 111. The fastener 130 also has a slot 134 configured to receive a driver for driving the fastener 130 when securing the printed wiring board 110 to the mount 120. Drivers of the type used for this purpose are familiar to those skilled in the pertinent art and are not illustrated or described herein. As hereinafter described, the opening angle of the conical head 132 is such that the conical head 132 produces both radial 202 and axial forces 203 on the printed wiring board 110. In one embodiment the radial forces 202 exceed the axial forces 203.

Turning now to FIG. 2, illustrated is a breakout view of a portion of the embodiment illustrated in FIG. 1 wherein the conical head 132 of the fastener 130 engages the rim 133 of the mounting hole 111. When the conical head 132 of the fastener 130 engages the rim 133 of the mounting hole 111, frictional force is generated to countervail the driver torque and eventually balance a preset driver torque. Resistance against the fastener 130 from the circumferential rim 133 of the mounting hole 111 causes a force (F) 201 normal or perpendicular to the conical head 132 that can be broken down into a radial force (F_{radial}) 202 and an axial force (Fₐₓᵢₐₗ) 203. The conical head 132 of the fastener has an opening angle 204 such that the increased frictional torque produced to countervail and balance the driver torque reduces the resultant axial force 203 on the printed wiring board. In one embodiment the radial force 202 exceeds the axial force 203. In another embodiment the opening angle 204 is about 25 degrees.

Although the illustrated rim 133 of the mounting hole 111 in the printed wiring board shows a sharp edge 133, those skilled in the pertinent art will understand that the edge can be chamfered or radiused with like results. Because the materials used to manufacture a printed wiring board 110 are relatively soft, compression will likely cause a portion of the rim 133 of the mounting hole 111 to be chamfered as it reacts to the conical shape of the fastener 130 when driven into place.

Turning again to FIG. 1, the illustrated embodiment shows the fastener 130 to be a machine screw. Machine screws such as this are frequently used to secure a printed wiring board 110 to a heat transfer device 120, also known as a heat sink, commonly used to dissipate heat generated by a component 140 or plurality of components 140. Of course those skilled in the pertinent art will recognize that the FIGs herein illustrating various embodiments are not to scale and that the actual screws or fasteners 130 used are often quite small. This means the size of the opening angle 204 is in large part dependent on the size of driver required to secure the fastener 130.

Turning now to FIG. 3 illustrated is an embodiment where a printed wiring board 110 is secured to a mount 120 using a threaded bolt 310 as a fastener 130, which bolt 310 is secured by a machine nut 320. It is readily apparent that the principles described above relating to a conical shaped head 132 of a fastener 130 are equally applicable to the head of a bolt 310 as well as other fastener types used to attach a printed wiring board 110 to a mount 120.

Turning now to FIG. 4, illustrated is an embodiment of a printed wiring board 110 and mount 120, where the mount 120 is a heat sink or heat transfer device 410. In order to efficiently transfer heat from a component 140 on the printed wiring board to the heat transfer device 410, it is important to maximize surface contact between the printed wiring board 110 and the heat transfer device 410. To improve contact and the consequent transfer of heat, some embodiments include a layer of thermally conductive material sandwiched between the printed wiring board 110 and the heat transfer device 410. Thermally conductive material is relatively incompressible and, if the fastener 130 imparts substantial axial force 203, flows radially and thins axially, forming non-flat geometries to which the printed wiring board 110 must conform. These non-flat geometries can exert sufficient pressure and strain the printed wiring board 110 and potentially cause significant component 140 damage. The illustrated embodiment alleviates this problem by using a fastener 130 with a conical head 132 to increase radial force 202 relative to axial force 203. This results in a decrease in total axial force 203 and, in turn, decreases strain on the printed wiring board 110.

Turning now to FIG. 5, illustrated is an embodiment of a fastener 130 with a conical head 132 used to fasten a printed wiring board 110 to a mount 120 that is a chassis 500 for an electronic device. In this embodiment, the chassis 500 has electronic components 140 mounted on it. Another aspect of the chassis 500 could support other printed wiring boards 110 or the chassis could actually be a rack for a number of electronic devices.

Turning now to FIG. 6, illustrated is a flow chart of a method of manufacturing 600 an embodiment of an electronics assembly 100. The method commences with a start step 610. In a locate step 620, a printed wiring board 110 having a mounting hole 111 is located over a mount 120. In one aspect, the mount 120 is a heat transfer device 410 while in another the mount is a chassis 500 for an electronic device. In an insert fastener step 630, a fastener 130 having a conical head 132 configured to receive a driver is inserted through the mounting hole 111. In an engage mount with fastener step 640 the fastener 130 engages the mount 110. In one embodiment, the conical head 132 has an opening angle 204 configured to produce radial forces 202 that exceeds axial forces 203 as the conical head bears against the rim 133 of the mounting hole 111. In one embodiment the opening angle is about 25 degrees. One aspect provides for a fastener 130 to be threaded. In a drive fastener step 650 a driver is used to drive the fastener 130 until the conical head 132 bears against the rim 133 of the mounting hole 111 and produces increasing frictional torque to countervail and eventually balance a predetermined torque of the driver. The method concludes with an end step 660. The foregoing method has application anywhere a user wishes to assure the intimate contact of plate like structures without inducing full torque limiting normal forces on the interface.

Those skilled in the art to which this application relates will appreciate that other and further additions, deletions, substitutions and modifications may be made to the described embodiments.

1. An electronics assembly, comprising:
a printed wiring board comprising a mounting hole, said mounting hole comprising a rim;
a mount; and
a fastener comprising a body and a conical head, said fastener configured to secure said printed wiring board to said mount, said body configured to pass through said mounting hole on said printed wiring board and to releasably engage said mount, said conical head configured to receive a driver torque, and to engage said rim of said mounting hole and to thereby produce an frictional torque to balance said driver torque.

2. An electronics assembly as recited in claim 1 wherein said mount is a heat transfer device.

3. An electronics assembly as recited in claim 1 wherein said mount is a chassis for an electronics device.

4. An electronics assembly as recited in claim 1 wherein said fastener is threaded.

5. An electronics assembly as recited in claim 4 wherein said fastener is a screw.

6. An electronics assembly as recited in claim 4 wherein said fastener is a bolt secured by a nut.

7. An electronics assembly as recited in claim 1 wherein said conical head has an opening angle producing both radial and axial forces on said printed wiring board, said radial forces exceeding said axial forces.

8. An electronics assembly as recited in claim 7 wherein said opening angle of said conical head is about 25 degrees.

9. A fastener for securing a printed wiring board of a printed wiring assembly to a mount, comprising:
a body configured to pass through a mounting hole on said printed wiring board and engage said mount; and
a conical head configured to receive a driver torque, said conical head further configured to engage a rim of said mounting hole and produce an increasing frictional torque to balance said driver torque.

10. A fastener as recited in claim 9 wherein said mount is a heat transfer device.

11. A fastener as recited in claim 9 wherein said mount is a chassis for an electronics device.

12. A fastener as recited in claim 9 wherein said fastener is threaded.

13. A fastener as recited in claim 12 wherein said fastener is a screw.

14. A fastener as recited in claim 12 wherein said fastener is a bolt secured by a nut.

15. A fastener as recited in claim 9 wherein said conical head has an opening angle causing both radial and axial forces on said printed wiring board, said radial forces exceeding said axial forces.

16. A fastener as recited in claim 15 wherein said opening angle of said conical head is about 25 degrees.

17. A method of manufacturing an electronics assembly, comprising:
locating a printed wiring board comprising a mounting hole therein over a mount;
inserting a fastener comprising a conical head configured to receive a driver through said mounting hole;
engaging said mount with said fastener;
driving said fastener until said conical head bears against a rim of said mounting hole; and
engaging said rim with said conical head to produce a frictional torque to balance a predetermined torque of said driver.

18. A method of manufacturing as recited in claim 17, wherein said mount is a heat transfer device.

19. A method of manufacturing as recited in claim 17, wherein said mount is a chassis for an electronics device.

20. A method of manufacturing as recited in claim 17, wherein said fastener is threaded.

21. A method of manufacturing as recited in claim 20 wherein said fastener is a screw.

22. A method of manufacturing as recited in claim 20 wherein said fastener is a bolt secured by a nut.

23. A method of manufacturing as recited in claim 17 herein said conical head has an opening angle producing both radial and axial forces on said printed wiring board, said radial forces exceeding said axial forces.

24. A method of manufacturing as recited in claim 23, wherein said opening angle of said conical head is about 25 degrees.

25. An electronics assembly, comprising:
a printed wiring board comprising a mounting hole, said mounting hole comprising a rim;
a mount; and
a fastener comprising a body and a conical head, said fastener configured to secure said printed wiring board to said mount, said body configured to pass through said mounting hole of said printed wiring board and to releasably engage said mount, said conical head configured to bear against said rim, an opening angle of said conical head being such that said conical head produces both radial and axial forces on said printed wiring board, said radial force exceeding said axial force.

26. An electronics assembly as recited in claim 25 wherein said mount is a heat transfer device.

27. An electronics assembly as recited in claim 25 wherein said mount is a chassis for an electronics device.

28. An electronics assembly as recited in claim 25 wherein said fastener is threaded.

29. An electronics assembly as recited in claim 28 wherein said fastener is a screw.

30. An electronics assembly as recited in claim 28 wherein said fastener is a bolt and nut.

31. An electronics assembly as recited in claim 25 wherein said opening angle of said conical head is about 25 degrees.

32. An electronics assembly as recited in claim 7 wherein said opening angle of said conical head is between 20 and 30 degrees.

33. A fastener as recited in claim 15 wherein said opening angle of said conical head is between 20 and 30 degrees.

34. A method of manufacturing as recited in claim 23 herein said opening angle of said conical head is between 20 and 30 degrees.

35. An electronics assembly as recited in claim 25 wherein said opening angle of said conical head is between 20 and 30 degrees.
